(19) United States
(12) Patent Application Publication
(10) Pub. No.: US 2026/0052721 A1
(43) Pub. Date: Feb. 19, 2026

(54) SEMICONDUCTOR DEVICE WITH SYNCHRONOUS OPTOELECTRONIC GATE

(71) Applicant: The Hong Kong University of Science and Technology, Hong Kong (CN)

(72) Inventors: Jing CHEN, Hong Kong (CN); Tao CHEN, Hong Kong (CN); Haochen ZHANG, Hangzhou (CN); Zheng WU, Hong Kong (CN)

(21) Appl. No.: 19/021,239

(22) Filed: Jan. 15, 2025

Related U.S. Application Data
(60) Provisional application No. 63/683,711, filed on Aug. 16, 2024.

(51) Int. Cl. H10D 30/47; H03K 17/687; H10D 62/85; H10F 39/00; H10F 39/10; H10F 55/00

(52) U.S. Cl. CPC H10D 30/4755; H03K 17/687; H10D 62/8503; H10F 39/103; H10F 39/8037; H10F 55/18; H03K 2017/6875

(57) ABSTRACT

The semiconductor device includes a high electron mobility transistor (HEMT) and a light emitter. The HEMT has a nucleation layer, buffer layer, channel layer, barrier layer, source and drain electrodes, p-doped III-V layer, and gate electrode. The nucleation layer is on a substrate, with the buffer and channel layers stacked above it. A 2DEG region forms at the interface between the channel and barrier layers. The source and drain electrodes are on the barrier layer, and the p-doped III-V layer is formed to achieve a desired threshold voltage. The gate electrode is placed between the source and drain. The light emitter is positioned above the HEMT, emitting an optical signal synchronized with the gate drive signal to create a synchronous optoelectronic-gated switch.

### TECHNICAL FIELD

The present invention relates to nitride-based semiconductor devices; and more particularly to a semiconductor device featuring a synchronous optoelectronic gate.

### BACKGROUND

Power switches are electronic devices used to control and convert electrical power within power systems. They play a critical role in power management systems, energy conversion systems and electrical equipment. To achieve low power dissipation, power devices are required to deliver low on-state resistance and low off-state leakage (i.e., high breakdown voltage). However, there is a fundamental trade-off between the on-resistance (RON) and breakdown voltage (BV) of power devices, determined by material properties and characterized by Baliga's figure of merit (BFOM). Wide-bandgap semiconductors, such as GaN and silicon carbide (SiC), feature higher BFOM over silicon due to the wider bandgap energy and are more favorable for energy-efficient power electronics.

Commercialized GaN power devices are represented by p-GaN gate high electron mobility transistors (HEMTs) with p-GaN gate structures for enhancement-mode (E-mode) operation, which have been widely used in many types of consumer electronic applications.

Compared to silicon-based power devices, p-GaN gate HEMT devices feature a high-concentration, high-mobility two-dimensional electron gas (2DEG) channel. The channel material exhibits a higher critical breakdown electric field, enabling a significant increase in breakdown voltage while reducing R_{ON}, thereby providing considerable energy-saving potential for power systems. However, despite the unique material advantages of gallium nitride, the optimization and improvement of GaN power devices remain limited.

For example, p-GaN gate HEMT device has a trade-off between the threshold voltage and the conductivity of the 2DEG region. Induced by the polarization effect of the AlGaN/GaN heterojunction, the 2DEG density increases with the AlGaN barrier thickness. However, with a thick AlGaN barrier, 2DEG under the p-GaN gate cannot be depleted and the device exhibits a negative threshold voltage, which does not favor fail-safe operation. As such, for E-mode p-GaN gate HEMT devices, there is a limit of the 2DEG density and the on-resistance.

In silicon-based power devices, the conductivity of the channel can be modulated by minority carrier injection, significantly reducing the on-resistance of the device. In p-GaN gate HEMTs, the presence of holes in the p-GaN layer gives rise to the possibility of conductivity modulation through minority carrier injection to further lower the on-resistance. However, compared with indirect-bandgap silicon and silicon carbide, as gallium nitride is a direct bandgap semiconductor and thus the ultrashort minority carrier lifetime (˜10 ns), conductivity modulation is not effective in channel. In p-GaN Gate HEMTs, under forward gate bias, holes are injected to the 2DEG region and the buffer layer. In the 2DEG region, the injected holes would rapidly recombine with electrons. In the buffer layer, the injected holes would not effectively modulate on-state channel conductivity but increase the off-state leakage.

Therefore, for p-GaN gate HEMT devices, there is a need to develop a conductivity modulation technique that can simultaneously reduce the on-state resistance and maintain a low off-state leakage.

### SUMMARY OF INVENTION

It is an objective of the present invention to provide devices and methods to address the aforementioned shortcomings and unmet needs in the state of the art.

In the present invention, a semiconductor device featuring a synchronous optoelectronic gate for enhanced conductivity modulation is disclosed. The device is synchronously controlled by electrical and optical signals through field effect and photogating effect. As one embodiment, a gallium nitride (GaN) high-electron-mobility transistor (HEMT) and a light-emitting device as the photon source are provided. The GaN HEMT comprises a substrate layer, a buffer layer, a channel layer, a barrier layer, a p-doped III-V layer, and/or a n-type GaN layer. The gate electrode is transparent or semi-transparent, allowing the p-doped III-V layer to absorb optical signals. Optical signals carrying above-bandgap-energy photons (greater than that of the p-GaN layer) are generated from a light-emitting device that is co-packaged or monolithically integrated with the GaN HEMT and positioned above the GaN HEMT. The device allows fast generation and removal of holes in the p-GaN gate for the modulation of electron concentration in the channel underneath and the conductivity of the channel, providing a low on-resistance and a high on-off current ratio.

In accordance with a first aspect of the present invention, a semiconductor device is provided. The semiconductor device includes a high electron mobility transistor (HEMT) and a light emitter. The HEMT includes a nucleation layer, a buffer layer, a channel layer, a barrier layer, a source electrode and a drain electrode, a p-doped III-V layer, and a gate electrode. The nucleation layer is disposed on a substrate. The buffer layer is disposed on the nucleation layer. The channel layer is disposed on the buffer layer. The barrier layer is disposed on the channel layer with a two-dimensional electron gas (2DEG) region generated at an interface between the channel layer and the barrier layer. The source electrode and the drain electrode are disposed over the barrier layer. The p-doped III-V layer is disposed on the barrier layer. The gate electrode is located between the source electrode and the drain electrode and is disposed on the p-doped III-V layer. The gate electrode is applied with a gate drive signal. The light emitter is disposed above the p-GaN HEMT and is configured to provide an optical signal propagated toward the gate electrode and the p-doped III-V layer of the HEMT. The light emitter is driven to emit the optical signal upon receiving an emission-enabling signal synchronized with the gate drive signal, so as to establish a synchronous optoelectronic-gated switch.

By the configuration, a synchronous optoelectronic-gated switch (SOGS) is achieved. In the SOGS device, in addition to controlling the channel through electrical control signals, optical signals are generated for conductivity enhancement through photogating effect. During the on state, in addition to electrical signals from the gate driver, the above-bandgap-energy photons are utilized as optical drive signals to generate electron-hole pairs in the gate stack of a GaN HEMT. Assisted by the electric field, electrons are swept to the gate electrode and holes accumulate in the p-doped III-V layer, which induces more electrons in the channel and enhances the channel conductivity. During the off state, the device is turned off by electrical signals with optical signals synchronously removed. The accumulated holes can be rapidly expelled from the gate stack, maintaining the low off-state leakage.

### BRIEF DESCRIPTION OF DRAWINGS

Embodiments of the invention are described in more details hereinafter with reference to the drawings, in which:

FIG. 1A is a vertical cross-sectional view of a semiconductor device according to some embodiments of the invention;

FIG. 1B is a top plan-view of a semiconductor device according to some embodiments of the invention.

FIG. 2A shows a schematic diagram for a configuration of a synchronous optoelectronic-gated switch with a light emitter cooperating with a p-GaN gate HEMT according to some embodiments of the present invention;

FIG. 2B and FIG. 2C illustrate energy band diagrams along a cutline of FIG. 2A at the gate region during the on-state and the off-state, respectively, according to some embodiments of the present invention;

FIG. 3 is a vertical cross-sectional view of a semiconductor device according to some embodiments of the invention;

FIG. 4 is a top plan-view of a semiconductor device according to some embodiments of the invention;

FIG. 5 is a top plan-view of a semiconductor device according to some embodiments of the invention; and

FIG. 6 is a top plan-view of a semiconductor device according to some embodiments of the invention.

### DETAILED DESCRIPTION OF THE INVENTION

In the following description, semiconductor devices featuring synchronous optoelectronic gates and the likes are set forth as preferred examples. It will be apparent to those skilled in the art that modifications, including additions and/or substitutions may be made without departing from the scope and spirit of the invention. Specific details may be omitted so as not to obscure the invention; however, the disclosure is written to enable one skilled in the art to practice the teachings herein without undue experimentation.

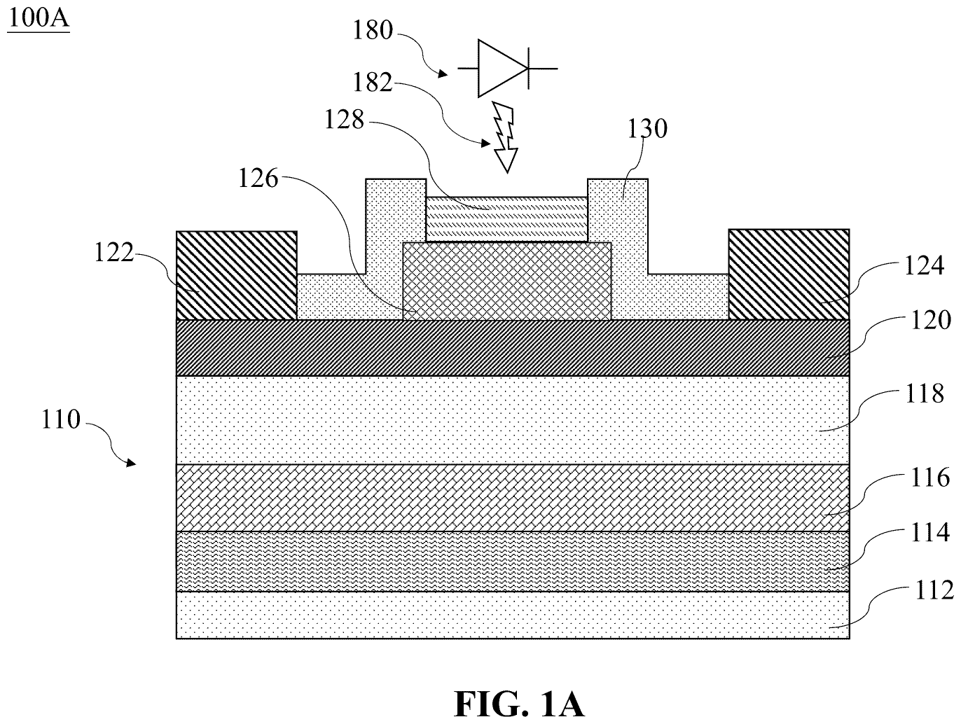

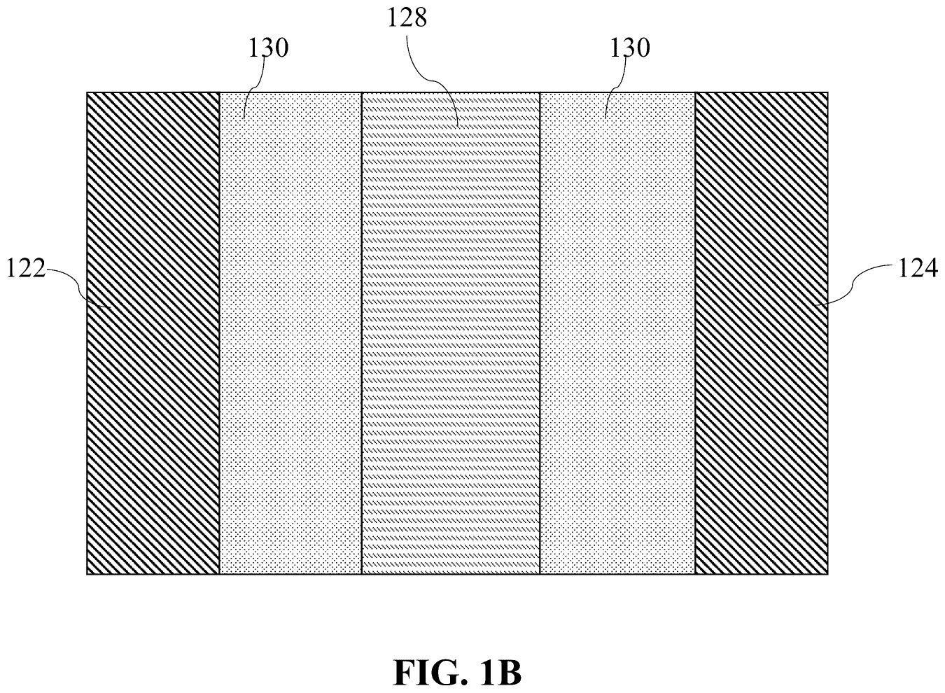

FIG. 1A is a vertical cross-sectional view of a semiconductor device 100A according to some embodiments of the invention; and FIG. 1B is a top plan-view of a semiconductor device 100A according to some embodiments of the invention. The semiconductor device 100A includes a high electron mobility transistor (HEMT) 110 and a light emitter 180.

The HEMT 110 includes a substrate 112, a nucleation layer 114, a buffer layer 116, a channel layer 118, a barrier layer 120, a source electrode 122 and a drain electrode 124, a p-doped III-V layer 126, a gate electrode 128, and a passivation layer 130.

The substrate 112 is a semiconductor substrate or an insulating substrate. For example, the substrate 112 may be made of materials such as Si, SiGe, SiC, AlN, GaN, gallium arsenide, p-doped Si, n-doped Si, sapphire, diamond, or semiconductor-on-insulator materials such as silicon-on-insulator (SOI), or other suitable substrate materials. In some embodiments, the substrate 112 may include group III elements, group IV elements, group V elements, or combinations thereof (e.g., III-V compounds) such as AlN and GaN. In other embodiments, the substrate 112 may include one or more features, such as a doped region, a buried layer, an epitaxial (epi) layer, or combinations thereof.

The nucleation layer 114 is disposed on the substrate 112, and the buffer layer 116 disposed on the nucleation layer 114. The nucleation layer 114 is formed between the substrate 112 and the buffer layer 116. The nucleation layer 114 can provide a transition to accommodate a mismatch/difference between the substrate 112 and the buffer layer 116 which includes a III-nitride material. The exemplary material of the nucleation layer 114 may include AlN, GaN, InN, or any of their alloys.

The buffer layer 116 is formed to reduce lattice and thermal mismatches between the substrate 112 and the channel layer 118, thereby curing defects due to the mismatches/difference. The buffer layer 116 may include a III-V compound, including aluminum, gallium, indium, nitrogen, or combinations thereof. In some embodiments, materials of the buffer layer 116 may further include, AlN, GaN, InN, AlGaN, InAlGaN, or combinations thereof.

The channel layer 118 is disposed on the buffer layer 116. The barrier layer 120 is disposed on the channel layer 118. The channel layer 118 and the barrier layer 120 are formed using nitride-based materials. The nitride-based materials of the channel layer 118 may include nitrides or group III-V compounds, such as AlN, GaN, InN, or their alloys. For example, the nitride-based materials of the channel layer 118 may further include InₓAl_{y}Ga_{(1-x-y)}N where x+y≤1, Al_{y}Ga_{(1-y)}N where y≤1. The nitride-based materials of the barrier layer 120 may include binary III-nitride compound, ternary III-nitride, quaternary III-nitride, AlN, AlGaN, InAlN, InAlGaN, or combinations thereof, such as InₓAl_{y}Ga_{(1-x-y)}N where x+y≤1, Al_{y}Ga_{(1-y)}N where y≤1. The barrier layer 120 may be formed as one single layer or as a stack of layers including AlN, GaN, InN, or their alloys with doped or undoped regions. For example, the barrier 120 could be AlN, GaN, InN, or their alloys with doped or undoped regions. Similarly, the nitride-based materials of the barrier layer 120 may further include InₓAl_{y}Ga_{(1-x-y)}N where x+y≤1, Al_{y}Ga_{(1-y)}N where y≤1.

As a HEMT device, the materials for the channel layer 118 and the barrier layer 120 are chosen such that the bandgap of the barrier layer 120 is greater than that of the channel layer 118. This difference in bandgap results in distinct electron affinities, forming a heterojunction between the two layers. This configuration allows the channel layer and barrier layer to function as intended, creating a triangular potential well at their interface. Due to the unique polarization effect of III-V nitrides, electrons accumulate in this well, forming a two-dimensional electron gas (2DEG) region adjacent to an interface/a heterojunction between the channel layer 118 and the barrier layer 120.

The source electrode 122 and the drain electrode 124 are formed over the channel layer 118 and the barrier layer 120. In some embodiments, the source electrode 122 and the drain electrode 124 may include metals, alloys, doped semiconductor materials (e.g., doped crystalline silicon), compounds such as silicides and nitrides, other conductor materials, or combinations thereof. For example, the source electrode 122 and the drain electrode 124 may include Ti, Ta, TiN, Al, W, Au, AlSi, AlCu, Ni, Pt, or combinations thereof. In some embodiments, each of the source electrode 122 and the drain electrode 124 may be a single layer, or plural layers of the same or different composition. The source electrode 122 and the drain electrode 124 can form ohmic contacts with the barrier layer 120.

The p-doped III-V layer 126 is disposed on top of the barrier layer 120, with the gate electrode 128 disposed on the top of p-doped III-V layer 126. The p-doped III-V layer 126 and the gate electrode 128 are located between the source electrode 122 and the drain electrode 124.

In some embodiments, the p-GaN gate HEMT 110 operates in enhancement mode and remains in a normally-off state when the gate electrode 128 is at approximately zero bias. The p-doped III-V layer 126 forms at least one p-n junction with the barrier layer 120, achieving a desired threshold voltage with depleting the 2DEG region in the region beneath the gate electrode 128. This depletion by the p-GaN gate alters the electron concentration in that specific portion of the 2DEG region compared to the rest, effectively blocking current flow in this area. In other embodiments, the p-GaN gate HEMT 110 is a depletion-mode device, which remains in a normally-on state at approximately zero gate bias. In such configuration, a high electron concentration persists in the gate region of the 2DEG channel, enabling continuous current flow at approximately zero gate bias.

In one embodiment, the p-doped III-V layer 126 is a p-type doped III-V semiconductor layer, such as a p-type GaN layer formed by a single layer or by a stack of layers. In some embodiments, the p-doped materials are achieved by using a p-type impurity, such as Be, Mg, Zn, Cd, and Mg with a wide range of doping concentrations. In the enhancement mode, the p-doped III-V layer 126 can bend the underlying band structure upwards and deplete the gate region of the 2DEG channel, achieving an off-state condition. In some embodiments, the p-doped III-V layer 126 can be formed using other p-type materials, such as p-doped III-V, p-type AlGaN, p-type InN, p-type AlInN, p-type InGaN, p-type AlInGaN, or combinations thereof.

In some embodiments, the gate electrode 128 is formed using conductive materials such as thin metal, which may include thin metal alloys, thin metal nitrides, metal oxides, or combinations thereof. In some embodiments, the gate electrode 128 is formed using heavily doped semiconductors, Ni, Ti, Al, Ag, Au, W, Cr, TiN, TiW, ITO, or combinations thereof. In some embodiments, the gate electrode 128 is optically transparent or semi-transparent, allowing light or optical signals to pass through.

The passivation layer 130 is disposed over the barrier layer 120 and covers sidewalls of the p-doped III-V layer 126 and the gate electrode 128. The passivation layer 130 includes at least one dielectric or isolation material, including SiNₓ, SiOₓ, Si₃N₄, SiON, SiC, SiBN, SiCBN, Al₂O₃, AlN, AlON, GaON oxides, nitrides, or combinations thereof. In some embodiments, the passivation layer 130 is a multi-layered structure, such as a composite dielectric layer of Al₂O₃/SiN, Al₂O₃/SiO₂, AlN/SiNₓ, AlN/SiO₂, or combinations thereof.

The light emitter 180 is disposed above the p-GaN gate HEMT 110 and is configured to provide an optical signal 182 propagated toward the gate electrode 128 and the p-doped III-V layer 126 of the p-GaN gate HEMT 110. For example, the light emitter 180 is vertically aligned with the gate electrode 128 of the p-GaN gate HEMT 110. In some embodiments, the light emitter 180 is a photodiode configured to provide the optical signal 182 having photons with an energy level higher than a bandgap energy of the p-doped III-V layer 126. For example, the optical signal 182 provided by the photodiode has photons with an energy level in an ultraviolet (UV) spectrum interval (e.g., greater than about 3.7 eV). This configuration is to facilitate the enhancement of the 2DEG density when the device is turned on. In some embodiments, the light emitter 180 may be a plurality of sub-light-emitting components in series or parallel.

The light emitter 180 can cooperate with the p-GaN gate HEMT 110 to achieve/establish a synchronous optoelectronic-gated switch (SOGS) for the p-GaN gate HEMT 110. For example, the light emitter 180 is driven to emit the optical signal 182 upon receiving an emission-enabling signal, and the gate electrode 128 is applied with a gate drive signal, in which the emission-enabling signal is synchronized with the gate drive signal. In some embodiments, the light emitter 180 is co-packaged or monolithically integrated with the p-GaN gate HEMT 110.

The p-GaN gate HEMT 110 is controlled by the gate drive signal applied to the gate electrode 128 and the optical signal 182 generated from the light emitter 180. As the p-GaN gate HEMT 110 is driven by a gate drive signal applied to the gate electrode 128, the conductivity of the 2DEG region is modulated through capacitive coupling between the gate electrode 128 and the channel of the channel layer 118, thereby gradually turning-on the channel allowing a current that flows from the source electrode 122 to the drain electrode 124. Simultaneously, the light emitter 180 generates above-bandgap photons as the optical signal 182. The above-bandgap-energy photons transmit through the gate electrode 128 and then are absorbed by the p-doped III-V layer 126, generating electron-hole pairs. The generated electrons are swept to the gate electrode 128 and the holes are accumulated in the p-doped III-V layer 126, inducing more electrons in the 2DEG region and greatly enhancing the channel conductivity.

As such, synchronous control of the gate drive signal and the emission-enabling signal, which generates excessive holes during the on-state and removes these holes during the off-state, allows the p-GaN gate HEMT 110 to deliver low on-resistance, low off-state leakage.

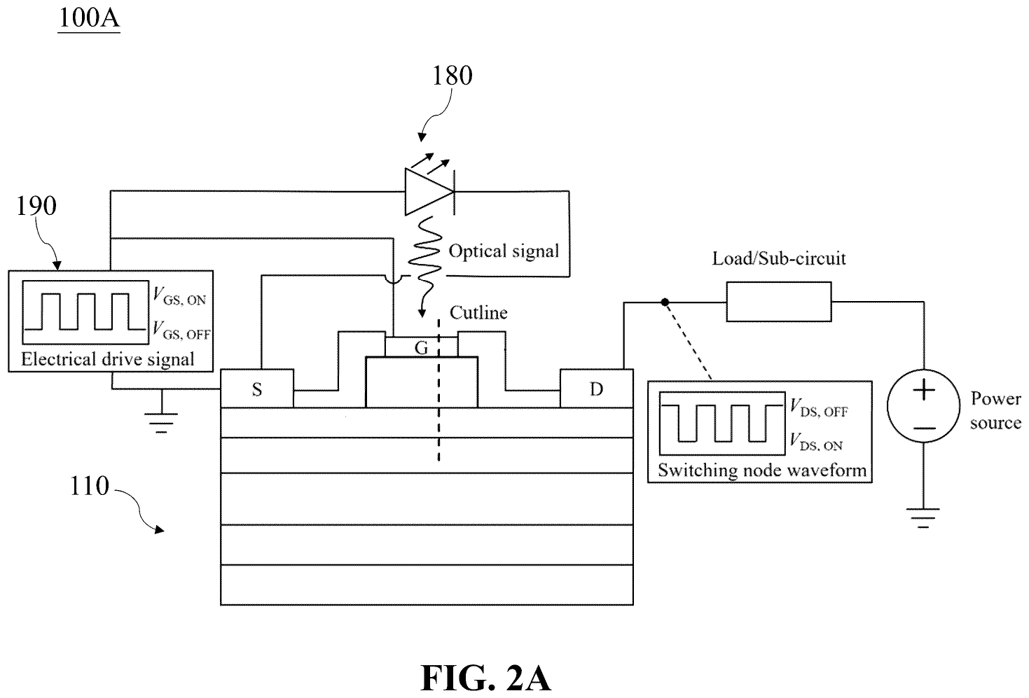

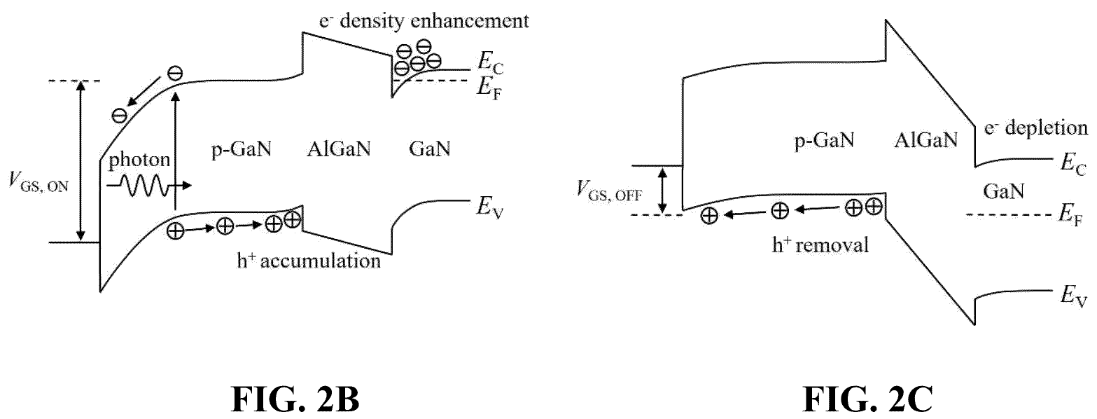

FIG. 2A shows a schematic diagram for a configuration of a synchronous optoelectronic-gated switch with a light emitter cooperating with a p-GaN gate HEMT according to some embodiments of the present invention. The p-GaN gate HEMT 110 and the light emitter 180 as afore-described are arranged. The device 100A further includes a gate driver 190 configured to send the gate drive signal and the emission-enabling signal to synchronously control the p-GaN gate HEMT 110 and the light emitter 180.

The light emitter 180 is a photodiode having an anode electrically coupled to the gate driver 190 and a cathode electrically coupled to the source electrode of the p-GaN gate HEMT 110, and the gate electrode is coupled with the gate driver 190. Also, the anode of the light emitter 180 and the gate electrode of the p-GaN gate HEMT 110 are electrically coupled to the same node and then to the gate driver 190 through the node. This is to synchronously control the p-GaN gate HEMT 110 and the light emitter 180 as the gate drive signal and the emission-enabling signal can be sent and transmitted simultaneously.

FIG. 2B and FIG. 2C illustrate energy band diagrams along a cutline of FIG. 2A at the gate stack during the on-state and the off-state, respectively, according to some embodiments of the present invention. In FIG. 2B and FIG. 2C, p-GaN represents he p-doped III-V layer 126; AlGaN represents the barrier layer 120; and the GaN represents the channel layer 118.

To turn on the SOGS, a gate drive signal is applied between the gate terminal G and the source terminal S of the p-GaN gate HEMT 110 for turning on the channel in the p-GaN gate HEMT 110, and the emission-enabling signal is applied between the anode and cathode of the light emitter 180 for generating above-bandgap-energy photons as optical signals.

As shown in FIG. 2B and FIG. 2C, electrons then accumulate in the channel of the p-GaN gate HEMT 110 with the effect of gate modulation and the electron density is further enhanced by photon-generated holes. The p-GaN gate HEMT 110 is turned on to conduct current and the drain-to-source voltage is switched to a low voltage (V_{DS,ON}). By switching the gate voltage to V_{GS,OFF}, and turning off the light emitter 180, excessive holes are removed and the 2DEG region/channel is depleted. The p-GaN gate HEMT 110 is thus non-conducting and the drain-to-source voltage is switched to a high voltage (V_{DS,OFF}). This switching mechanism provides control of power delivery and functional performance for the load/sub-circuit.

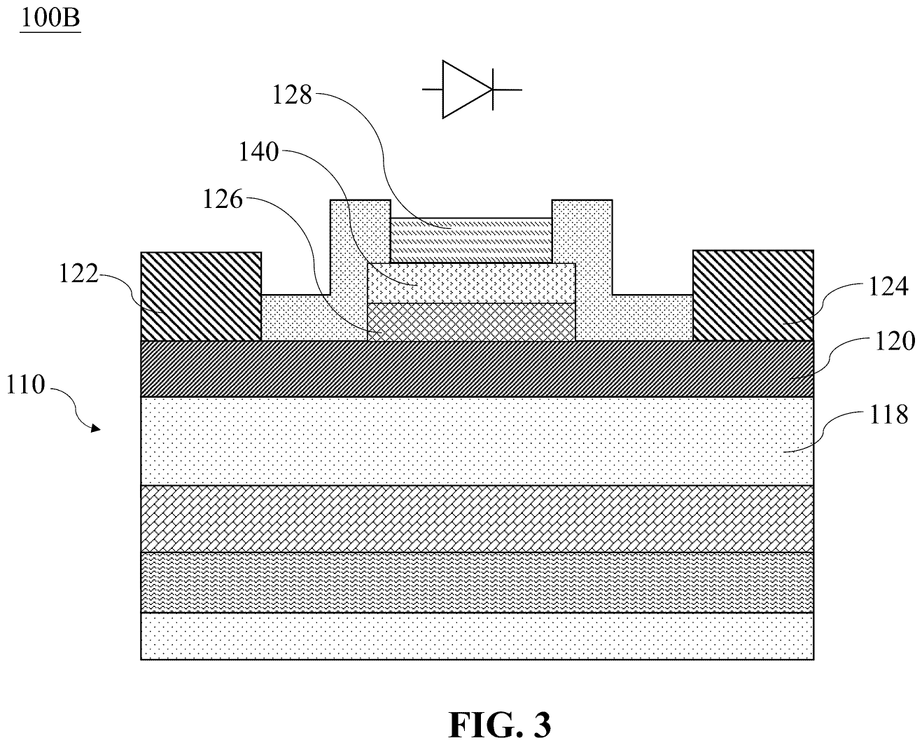

FIG. 3 is a vertical cross-sectional view of a semiconductor device 100B according to some embodiments of the invention. The semiconductor device 100B has a configuration similar to that of the semiconductor device 100A, except the p-GaN gate HEMT 110 of the semiconductor device 100B further includes an n-doped III-V layer 140 located between source electrode 122 and the drain electrode 124. The n-doped III-V layer 140 is disposed between the p-doped III-V layer 126 and the gate electrode 128 and make contact with the p-doped III-V layer 126 and the gate electrode 128 to form interfaces with both the p-doped III-V layer 126 and the gate electrode 128.

In some embodiments, the n-doped III-V layer 140 is an n-type doped III-V semiconductor layer, such as an n-type GaN layer formed by a single layer or by a stack of layers. In some embodiments, the n-doped materials are achieved by using an n-type impurity, such as Si, Ge, S, or Se, with a wide range of doping concentrations. In some embodiments, the n-doped III-V layer 140 can be formed using other n-type materials, such as n-doped III-V, n-type AlGaN, n-type InN, n-type AlInN, n-type InGaN, n-type AlInGaN, or combinations thereof.

The n-doped III-V layer 140 forms a depletion region between the p-doped III-V layer 126. The electric field in the depletion region facilitates the separation of the photogenerated electron-hole pairs, thereby enhancing the accumulation of photogenerated holes in the p-doped III-V layer 126. The 2DEG density is further enhanced during the on-state.

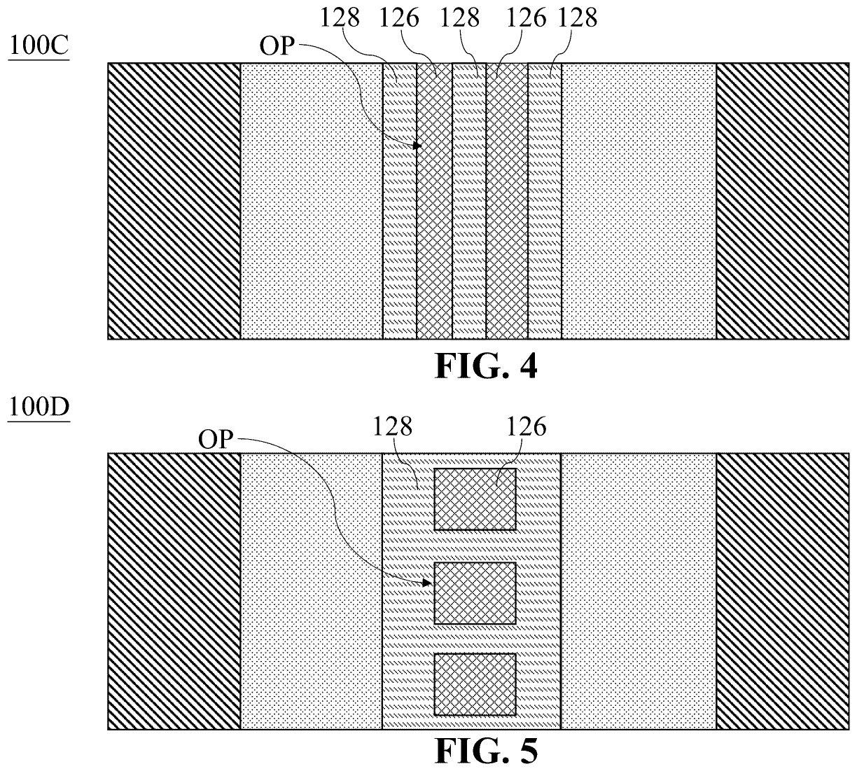

FIG. 4 is a top plan-view of a semiconductor device 100C according to some embodiments of the invention. The semiconductor device 100C has a configuration similar to that of the semiconductor device 100A, except the HEMT of the semiconductor device 100C includes the gate electrode 128 that exposes at least one portion of the p-doped III-V layer 126. Specifically, the gate electrode 128 covers the underlying p-doped III-V layer 126 and has window openings OP to expose at least one portion of the p-doped III-V layer 126 from the window openings OP. In the illustration of the FIG. 4, the gate electrode 128 has stripe patterns that form the window openings OP. The gate electrode 128, with its stripe patterns, creates window openings OP that enhance optical transmission efficiency by allowing more photons or optical signals from the light emitter to enter the p-doped III-V layer 126.

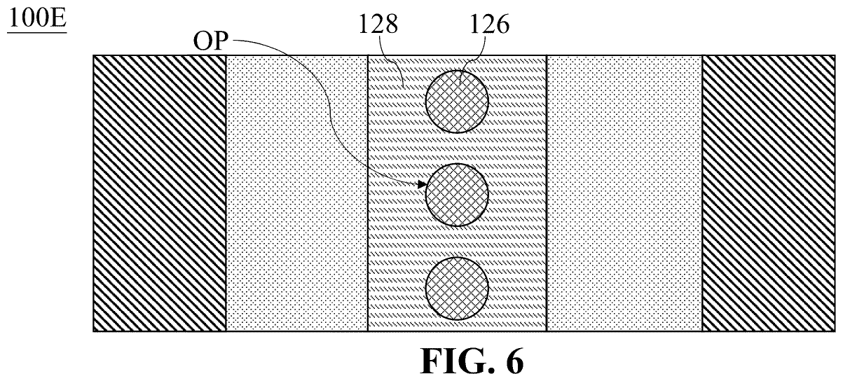

FIG. 5 is a top plan-view of a semiconductor device 100D according to some embodiments of the invention. The semiconductor device 100D has a configuration similar to that of the semiconductor device 100A, except the HEMT of the semiconductor device 100D includes the gate electrode 128 that exposes at least one portion of the p-doped III-V layer 126 with window openings OP. The gate electrode 128 has rectangular patterns that form the window openings OP to expose the p-doped III-V layer 126, enhancing optical transmission efficiency.

FIG. 6 is a top plan-view of a semiconductor device 100E according to some embodiments of the invention. The semiconductor device 100E has a configuration similar to that of the semiconductor device 100A, except the HEMT of the semiconductor device 100E includes the gate electrode 128 that exposes at least one portion of the p-doped III-V layer 126 with window openings OP. The gate electrode 128 has circular patterns that form the window openings OP to expose the p-doped III-V layer 126, enhancing optical transmission efficiency.

As discussed above, in the present invention, a synchronous optoelectronic-gated switch (SOGS), which is controlled by electrical signals and optical signals to enhance conductivity. During the “on” state, in addition to signals from the gate driver, above-bandgap-energy photons are used as optical drive signals to generate electron-hole pairs in the gate stack of a p-GaN gate HEMT. Assisted by the electric field, electrons are swept toward the gate electrode, and holes accumulate in the gate stack, inducing more electrons in the channel and enhancing channel conductivity. During the “off” state, the device is turned off by electrical signals, with optical signals removed synchronously. The accumulated holes can be rapidly expelled from the gate stack, maintaining low off-state leakage.

Spatial references such as “on,” “above,” “below,” and similar terms are defined relative to a component or plane as shown in the figure. These terms are for illustration only and do not limit the actual arrangement, provided the described embodiments retain their intended benefits.

It should be noted that while various structures are depicted as approximately rectangular in the illustrations, their actual shapes may differ in practice due to fabrication conditions. These shapes may include curves, rounded edges, or variations in thickness. The use of straight lines and right angles in the figures is merely a representational convenience for depicting layers and features.

In this disclosure, the terms “a,” “an,” and “the” should be interpreted to include both singular and plural forms unless explicitly specified otherwise by the context. Additionally, when describing embodiments, a component positioned “on” or “over” another component can refer to cases where the two components are directly in contact or where one or more intermediate components are situated between them.

The foregoing description of the present invention has been provided for the purposes of illustration and description. It is not intended to be exhaustive or to limit the invention to the precise forms disclosed. Many modifications and variations will be apparent to the practitioner skilled in the art.

The embodiments were chosen and described in order to best explain the principles of the invention and its practical application, thereby enabling others skilled in the art to understand the invention for various embodiments and with various modifications that are suited to the particular use contemplated.

1. A semiconductor device, comprising:
a high electron mobility transistor (HEMT), comprising:
a nucleation layer disposed on a substrate;
a buffer layer disposed on the nucleation layer;
a channel layer disposed on the buffer layer;
a barrier layer disposed on the channel layer with a two-dimensional electron gas (2DEG) region generated at an interface between the channel layer and the barrier layer;
a source electrode and a drain electrode disposed over the barrier layer;
a p-doped III-V layer disposed on the barrier layer; and
a gate electrode located between the source electrode and the drain electrode and disposed on the p-doped III-V layer, wherein the gate electrode is applied with a gate drive signal; and
a light emitter disposed above the HEMT and configured to provide an optical signal propagated toward the gate electrode and the p-doped III-V layer of the HEMT, wherein the light emitter is driven to emit optical signal upon receiving an emission-enabling signal synchronized with the gate drive signal, so as to establish a synchronous optoelectronic-gated switch.

2. The semiconductor device according to claim 1, further comprising a gate driver configured to send the gate drive signal and the emission-enabling signal to synchronously control the HEMT and the light emitter.

3. The semiconductor device according to claim 2, wherein the light emitter is a photodiode having an anode electrically coupled to the gate driver and a cathode electrically coupled to the source electrode of the HEMT, and the gate electrode of the HEMT is coupled with the gate driver.

4. The semiconductor device according to claim 3, wherein the anode of the light emitter and the gate electrode are electrically coupled to the same node and then to the gate driver through the node.

5. The semiconductor device according to claim 1, wherein the light emitter is a photodiode configured to provide the optical signal having photons with an energy level higher than a bandgap energy of the p-doped III-V layer.

6. The semiconductor device according to claim 5, wherein the optical signal provided by the photodiode has photons with an energy level in an ultraviolet (UV) spectrum interval.

7. The semiconductor device according to claim 1, wherein the gate electrode is optically transparent or semi-transparent.

8. The semiconductor device according to claim 1, wherein the light emitter is co-packaged or monolithically integrated with the HEMT.

9. The semiconductor device according to claim 8, wherein the light emitter is vertically aligned with the gate electrode of the HEMT.

10. The semiconductor device of claim 1, wherein the gate electrode of the HEMT covers the underlying p-doped III-V layer and has window openings to expose at least one portion of the p-doped III-V layer from the window openings.

11. The semiconductor device of claim 10, wherein the window openings have stripe patterns, rectangular patterns, circular patterns, or combinations thereof.

12. The semiconductor device of claim 1, wherein the HEMT further comprises an n-doped III-V layer disposed between the p-doped III-V layer and the gate electrode, forming interfaces with both the p-doped III-V layer and the gate electrode.

13. The semiconductor device of claim 1, wherein the light emitter comprises a plurality of sub-light-emitting components in series or parallel.

14. The semiconductor device of claim 1, wherein the HEMT further comprises a passivation layer covering sidewalls of the p-doped III-V layer and the gate electrode.

15. The semiconductor device of claim 1, wherein the barrier layer is a single layer or comprises a stack of layers.

16. The semiconductor device of claim 1, wherein the barrier layer comprises, AlN, GaN, InN, alloys thereof with doped or undoped regions.

17. The semiconductor device of claim 1, wherein the p-doped III-V layer is a p-GaN layer formed by a single layer or by a stack of layers.

18. The device of claim 1, wherein the gate electrode is made by thin metal or semiconductor, comprising thin metal alloy, thin metal nitride, metal oxide, heavily doped semiconductors, Ni, Ti, Al, Ag, Au, W, Cr, TiN, TiW, ITO, or combinations thereof.
